(19) United States
(12) Patent Application Publication
(10) Pub. No.: US 2026/0251704 A1
(43) Pub. Date: Aug. 27, 2026

(54) PROBE SUPPORT ASSEMBLY INCLUDING A PIEZOELECTRIC SENSOR ARRAY FOR ALIGNMENT OF A PROBE CARD ASSEMBLY AND METHODS OF OPERATING AND FORMING THE SAME

(71) Applicant: Taiwan Semiconductor Manufacturing Company Limited, Hsinchu (TW)

(72) Inventors: Jia-Yang Huang, Hsinchu (TW); Yu-Long Chen, Changhua City (TW); Guang-Sing Huang, Hsinchu (TW); Kai-Yi Tang, New Taipei City (TW)

(21) Appl. No.: 19/062,287

(22) Filed: Feb. 25, 2025

(51) Int. Cl. G01R 31/28; G01R 1/067; G01R 1/073; H10N 30/00; H10N 30/03

(52) U.S. Cl. CPC G01R 31/2891; G01R 1/0675; G01R 1/07342; G01R 1/07364; H10N 30/03; H10N 30/101

(57) ABSTRACT

A test apparatus may be operated by attaching a contact interface substrate including probe contact pads to a bottom of a probe card, and disposing a probe support assembly over the probe card. The probe support assembly includes a piezoelectric device array containing a plurality of piezoelectric unit devices. Each of the piezoelectric unit devices includes a respective piezoelectric sensor. An array of probe needles may be attached to the probe contact pads.

### BACKGROUND

Probe cards provide physical interfaces between automatic test equipment (ATE) and semiconductor wafers, and provide precise electrical testing of the semiconductor wafers. Warpage and unevenness in contact surfaces may be detrimental to and compromise the electrical connection between the probe needles and test pads on the semiconductor wafer. Methods for aligning the probe needles to the test pads with even downward pressure rely heavily on manual adjustments, which are labor-intensive and time-consuming. Misalignment of the probe needles relative to test pads undermines testing consistence, diminishes reliability of test data, and accelerates wear on the probe needles, shortening their operational lifespan and increasing maintenance frequency.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a schematic view of a test apparatus according to an embodiment of the present disclosure.

FIG. 2A is a vertical cross-sectional view of a first exemplary probe module assembly according to an embodiment of the present disclosure. FIG. 2B is a horizontal cross-sectional view along the horizontal plane B-B′ of the first exemplary probe module assembly of FIG. 2A. The vertical plane A-A′ in FIG. 2B is the cut plane of the vertical cross-sectional view of FIG. 2A. FIG. 2C is a horizontal cross-sectional view along the horizontal plane C-C′ of the first exemplary probe module assembly of FIG. 2A. The vertical plane A-A′ in FIG. 2C is the cut plane of the vertical cross-sectional view of FIG. 2A. FIG. 2D is a horizontal cross-sectional view along the horizontal plane D-D′ of the first exemplary probe module assembly of FIG. 2A. The vertical plane A-A′ in FIG. 2D is the cut plane of the vertical cross-sectional view of FIG. 2A.

FIG. 3A is a first vertical cross-sectional view of a piezoelectric device array according to an embodiment of the present disclosure. FIG. 3B is a second vertical cross-sectional view of the piezoelectric device array according to an embodiment of the present disclosure. FIG. 3C is a horizontal cross-sectional view of the piezoelectric device array along the horizontal plane C-C′ of the piezoelectric device array of FIGS. 3A and 3B. FIG. 3D is a horizontal cross-sectional view of the piezoelectric device array along the horizontal plane D-D′ of the piezoelectric device array of FIGS. 3A and 3B. FIG. 3E is a horizontal cross-sectional view of the piezoelectric device array along the horizontal plane E-E′ of the piezoelectric device array of FIGS. 3A and 3B. The vertical plane A-A′ in FIGS. 3C, 3D, and 3E is the cut plane of the first vertical cross-sectional view of FIG. 3A. The vertical plane B-B′ in FIGS. 3C, 3D, and 3E is the cut plane of the second vertical cross-sectional view of FIG. 3B.

FIG. 4 is a vertical cross-sectional view of a second exemplary probe module assembly according to an embodiment of the present disclosure.

FIG. 5 is a vertical cross-sectional view of a third exemplary probe module assembly according to an embodiment of the present disclosure.

FIG. 6 is a vertical cross-sectional view of a fourth exemplary probe module assembly according to an embodiment of the present disclosure.

FIG. 7 is a vertical cross-sectional view of a fifth exemplary probe module assembly according to an embodiment of the present disclosure.

FIG. 8 is a vertical cross-sectional view of a sixth exemplary probe module assembly according to an embodiment of the present disclosure.

FIG. 9 is a vertical cross-sectional view of a seventh exemplary probe module assembly according to an embodiment of the present disclosure.

FIG. 10A is plan view of a wafer after formation of test pads according to an embodiment of the present disclosure. FIG. 10B is a vertical cross-sectional view of the wafer along the vertical plane B-B′ of FIG. 10A.

FIG. 11 is a vertical cross-sectional view of a portion of the test apparatus of FIG. 1 during testing of a semiconductor die using test pads on the wafer according to an embodiment of the present disclosure.

FIG. 12A-12E illustrate a sequence of processing steps that may be used to form a probe module assembly of the present disclosure.

FIG. 13 is a first flowchart that illustrates the general processing steps for operating a test apparatus according to an aspect of the present disclosure.

FIG. 14 is a second flowchart that illustrates the general processing steps for manufacturing a test apparatus according to an aspect of the present disclosure.

FIG. 15 is a third flowchart that illustrates the general processing steps for manufacturing a test apparatus according to an aspect of the present disclosure.

### DETAILED DESCRIPTION

The following disclosure provides many different embodiments, or examples, for implementing various features of the provided subject matter. Specific examples of components and arrangements are described below to clarify the present disclosure. These are merely examples, and are not limiting. Drawings are not drawn to scale. Elements with the same reference numerals refer to the same element, and are presumed to have the same material composition and the same thickness range unless expressly indicated otherwise. All features of an original embodiment are presumed to be present in any derived embodiment unless expressly disclosed otherwise. Thus, features described with reference to related embodiments in the drawings and/or in the specification provide support for features in an embodiment. Embodiments are expressly contemplated in which multiple instances of any described element are repeated unless expressly stated otherwise. Embodiments are expressly contemplated in which non-essential elements are omitted even if such embodiments are not expressly disclosed but are known in the art.

Further, spatially relative terms, such as “beneath,” “below,” “lower,” “above,” “upper” and the like, may be used herein for ease of description to describe geometrical features among elements as illustrated in the figures. A first physical element is “embedded” with a second physical element if the entire volume of the first element is located within a hypothetical volume defined by a set of hypothetical surfaces having the least total surface area among all sets of hypothetical surfaces containing the entirety of the outer surfaces of the second element and topologically homeomorphic to a spherical surface. Such a set of hypothetical surfaces covers each opening, if present, in the outer surfaces with a minimum-area surface segment selected from all possible opening-free surface segments. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. Unless explicitly stated otherwise, each element having the same reference numeral is presumed to have the same material composition and to have a thickness within a same thickness range.

Related probe card systems face challenges in maintaining planarity and reliable contact between probe needles and semiconductor wafers during testing. These challenges may be due to mechanical warpage and uneven contact surfaces, which result in variations in electrical connections during testing, reducing the reliability of testing results and impacting manufacturing efficiency. Consumable materials like mylar films are frequently used to facilitate uniform contact pressure between the probe needles and the semiconductor wafers. However, such adjustment methods utilize manual adjustments, and may not be adapted to real-time changes in testing conditions. Embodiments of the present disclosure provide a probe card assembly enabling real-time planarity compensation. Specifically, a piezoelectric device array may be used to provide real-time detection and compensation of mechanical warpage. Thus, consistent contact between probe needles and the a semiconductor wafer may be maintained without use of consumable materials or manual adjustments.

The probe card assembly of the present disclosure may comprise at least one two-dimensional array of piezoelectric unit devices. Each piezoelectric unit device may comprise a vertical stack of a bottom electrode, a piezoelectric material portion, and a top electrode. The electrode pairs may be used to detect piezoelectric voltages generated by deformation of the piezoelectric material portion. The piezoelectric signals from the electrode pairs may be processed to generate a two-dimensional map of deformation of the piezoelectric material portions within the array. External voltages that are used to compensate the measured deformation of the piezoelectric material portions may be determined based on the two-dimensional map of deformation. The electrode pairs may be subsequently used to apply actuation voltages to the piezoelectric material portion such that the measured deformation of the piezoelectric material portions may be reduced and compensated by application of the actuation voltages. Various aspects of the present disclosure are now described in detail with reference to accompanying drawings.

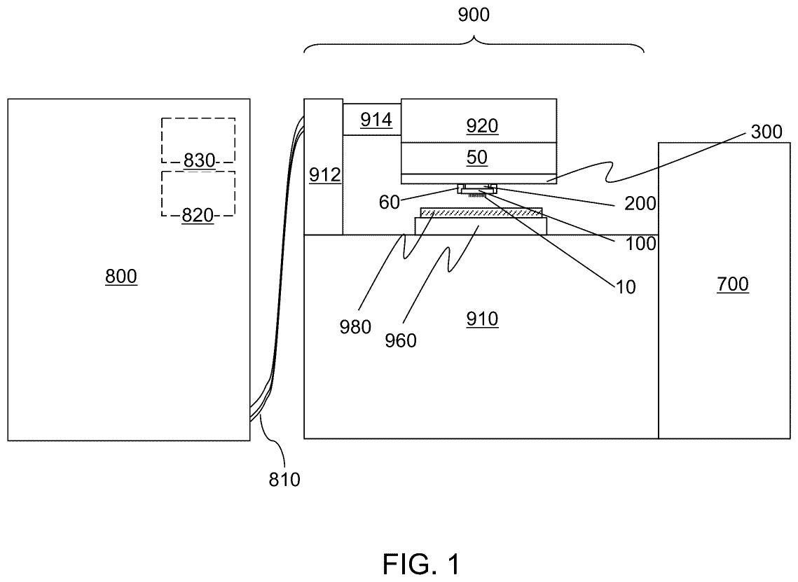

Referring to FIG. 1, an embodiment test apparatus illustrating an aspect of the present disclosure is provided. The embodiment test apparatus may include a tester electronics unit 800 including at least one computer and peripheral devices, a wafer prober 900 in communication with the tester electronics unit 800, for example, via signal and power cables 810, and an optional wafer conveyer unit 700 configured to load and unload a device under test (DUT) 980 to be tested on the wafer prober 900. The wafer prober 900 may include a wafer chuck 960 configured to hold a device under test (DUT) 980 thereupon, a prober frame 910 containing a stage drive unit configured to laterally drive the wafer chuck 960, a tester head 920 that overlies the wafer chuck 960, and tester head support structures (912, 914) configured to structurally support, and to provide movement to, the tester head 920.

According to an aspect of the present disclosure, a probe module assembly (10, 100, 200, 60, 300, 50) is provided, which is configured to enhance the planarity and stability of a probe card assembly (10, 100, 200, 60, 300) during wafer probing. The probe module assembly (10, 100, 200, 60, 300, 50) integrates at least one piezoelectric device array within a probe support assembly 50. The at least one piezoelectric device array is configured to provide real-time detection and compensation of mechanical irregularities, addressing limitations of conventional passive methods reliant on consumable materials such as mylar films.

The probe card 300 may comprise a printed circuit board (PCB) containing a plastic substrate and printed circuits thereupon. The probe card 300 is commonly referred to as a main board. A probe interface assembly (10, 100, 200, 60) may be attached to the bottom of the probe card 300. The probe interface assembly (10, 100, 200, 60) comprises a contact interface substrate 200, a plate assembly 100 including an upper guide plate, a lower guide plate, and a plurality dielectric spacer plates, a jig 60 configured to affix the plate assembly 100 to the probe card 300, and an array of probe needles 10. The combination of the probe interface assembly (10, 100, 200, 60) and the probe card 300 constitutes a probe card assembly (10, 100, 200, 60, 300).

A probe support assembly 50 may be attached to the top of the probe card 300. The probe support assembly 50 may comprise a stiffener (not expressly illustrated in FIG. 1), which may be attached to the backside of the probe card 300 to reduce structural deformation of the probe card 300 due to thermal and/or mechanical stress during use of the probe card 300. The probe support assembly 50 may be subsequently attached to the bottom of the tester head 920 using a suitable array of contact structures such as an array of spring-type contact pins. The combination of the probe card assembly (10, 100, 200, 60, 300) and the probe support assembly 50 is herein referred to as a probe module assembly (10, 100, 200, 60, 300, 50).

According to an aspect of the present disclosure, the probe support assembly 50 of the present disclosure comprises at least one piezoelectric device array including a respective array of piezoelectric unit devices. Each piezoelectric unit device is configured to generate a respective piezoelectric voltage that is proportional to vertical deformation of a respective piezoelectric material portion using a respective set of electrode pairs. The set of piezoelectric voltage from the piezoelectric unit devices is transmitted via a subset of the signal and power cables 810 to a piezoelectric sensing circuit 820 within the tester electronics unit 800. The tester electronics unit 800 may generate a two-dimensional map of deformations within each piezoelectric device array, and use a reverse-piezoelectric driver circuit 830 to generate actuation signals. The actuation signals may be applied to electrode pairs of a respective piezoelectric unit device to induce a reverse-piezoelectric effect, in which an externally applied voltage induces deformation of a piezoelectric material portion. Generally, the actuation signals are selected such that the reverse-piezoelectric effect works in a manner that decreases pre-existing deformation of the piezoelectric material portions. The planarity of the alignment between the probe card 300 and the texter head may be restored using electrical signals only without mechanical adjustment of components.

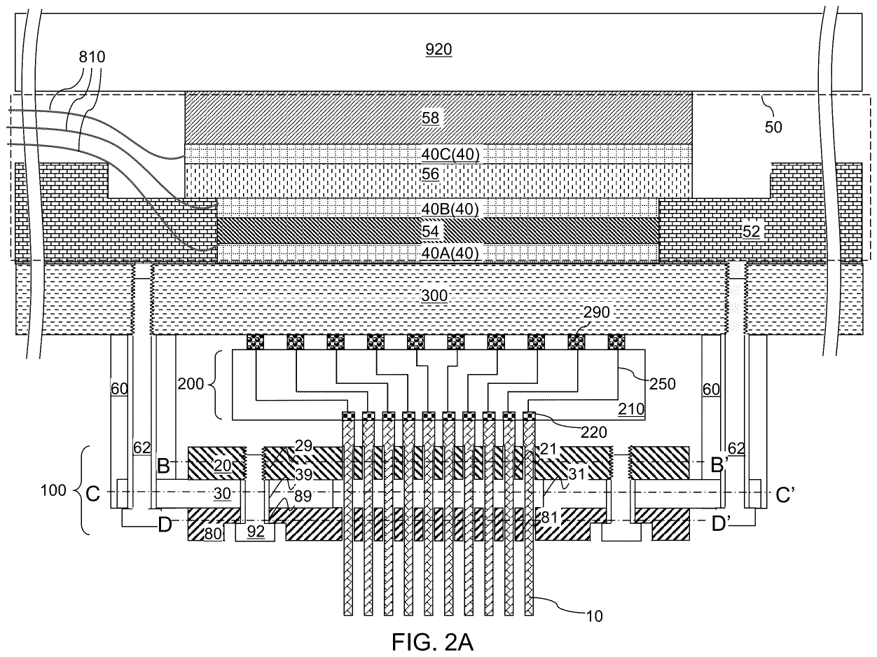

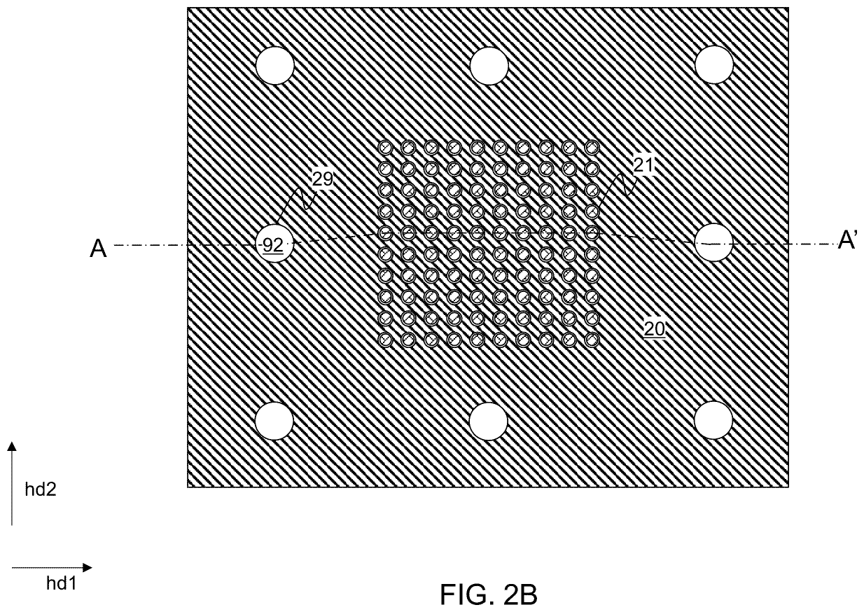

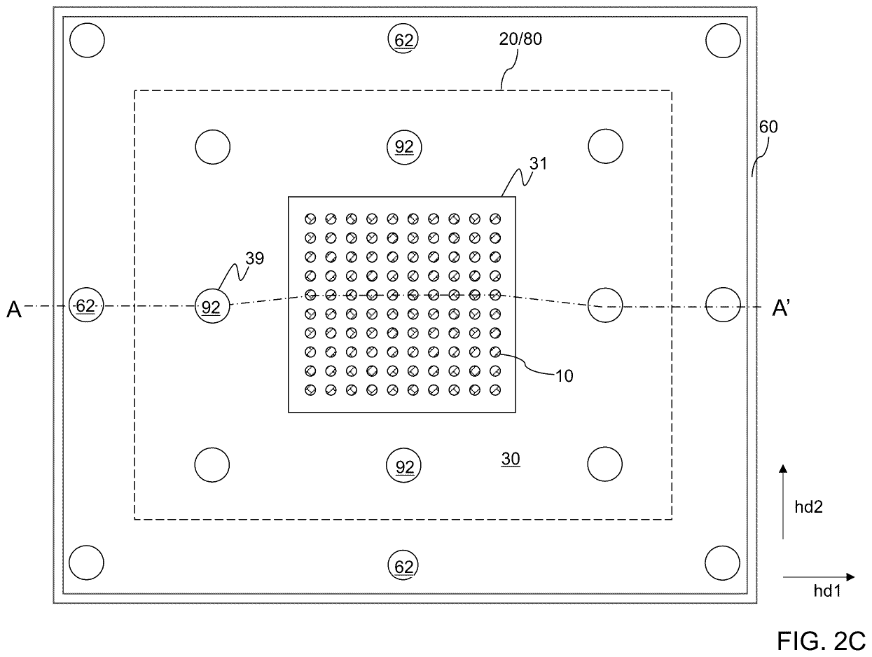

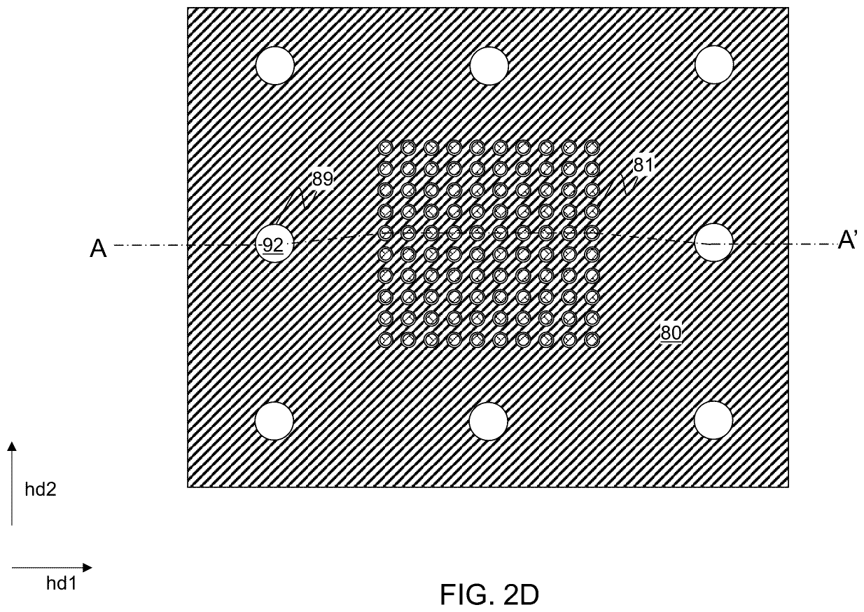

Referring to FIG. 2A-2D, various views of a first exemplary probe module assembly (10, 100, 200, 60, 300, 50) are illustrated. FIG. 2A is a vertical cross-sectional view of the first exemplary probe module assembly according to an embodiment of the present disclosure. FIG. 2B is a horizontal cross-sectional view along the horizontal plane B-B′ of the first exemplary probe module assembly of FIG. 2A. The vertical plane A-A′ in FIG. 2B is the cut plane of the vertical cross-sectional view of FIG. 2A. FIG. 2C is a horizontal cross-sectional view along the horizontal plane C-C′ of the first exemplary probe module assembly of FIG. 2A. The vertical plane A-A′ in FIG. 2C is the cut plane of the vertical cross-sectional view of FIG. 2A. FIG. 2D is a horizontal cross-sectional view along the horizontal plane D-D′ of the first exemplary probe module assembly of FIG. 2A. The vertical plane A-A′ in FIG. 2D is the cut plane of the vertical cross-sectional view of FIG. 2A. The first exemplary probe module assembly (10, 100, 200, 60, 300, 50) in FIG. 2A-2D may be incorporated as the probe module assembly (10, 100, 200, 60, 300, 50) in the embodiment test apparatus of FIG. 1.

A contact interface substrate 200 comprising probe contact pads 220 is provided. The contact interface substrate 200 may include a multilayer dielectric matrix 210 and redistribution structures 250 embedded in the multilayer dielectric matrix 210. The multilayer dielectric matrix 210 may include ceramic layers or organic layers. In embodiments in which the multilayer dielectric matrix 210 includes ceramic layers, the contact interface substrate 200 may be referred to as multilayer ceramic structure. In embodiments in which the multilayer dielectric matrix 210 include organic layers, the contact interface substrate 200 may be referred to as multilayer organic structure. A subset of the redistribution structure 250 may include an array of contact structures on a side that faces the probe card 300. The array of contact structures may have a greater pitch than the pitch of an array of probe needles 10 to be subsequently employed.

Generally, a probe card 300 is provided. The probe card 300 comprises a plastic substrate with printed circuits and contact structures designed to interconnect the probe interface assembly (10, 100, 200, 60) to the tester electronics unit 800. The probe card 300 comprises signal and power pathways for transmission of signals and power between the probe interface assembly (10, 100, 200, 60) to the tester electronics unit 800.

The contact interface substrate 200 may be attached to the probe card 300 through an array of interconnection structures 290, which may include an array of solder balls or may include an interposer including an array of vertical interconnection structures. The probe contact pads 220 may be located at the bottommost level of the redistribution structures 250, and may be connected to a respective one of the redistribution structures 250. The probe contact pads 220 may comprise gold pads.

A probe support assembly 50 may be disposed on the probe card 300. The probe support assembly 50 is configured to structurally support and align the probe card during testing. The probe support assembly 50 may comprise a stiffener 52 including an opening therein, a pusher 54 configured to fit into the opening in the stiffener 52, a backer having a greater lateral extent than the opening in the stiffener 52 and configured to support the backside, i.e., the upside, of the pusher 54, and a bridge beam 58 that is configured to provide structural reinforcement and flexibility.

The stiffener 52 maintains the rigidity of the probe support assembly 50 by preventing unwanted bending or flexing of the probe card 300. By creating a more robust connection between the probe card 300 and the probe support assembly 50, the stiffener 52 ensures that the probe module assembly (10, 100, 200, 60, 300, 50) remains stable during high-frequency testing, where small movements may impact signal accuracy.

The pusher 54, which fits into the opening in the stiffener 52, is designed to exert a controlled force on the probe needles 10 in order to ensure proper alignment and contact with a device under test (DUT), which may be a semiconductor die in a semiconductor wafer. The backer 56 supports the backside of the pusher 54. The backer provides additional structural support to the probe needles 10, and helps distribute the mechanical load evenly across the probe needles 10. The combination of the pusher 54 and the backer 56 reduces the likelihood of deformation under stress, thus ensuring that the probe needles 10 remain precisely aligned throughout the testing process.

The bridge beam 58 may be configured to allow for controlled vertical movement of the pusher 54 while maintaining alignment and stability under mechanical and thermal stresses. The bridge beam 58 within the probe support assembly 50 serves to enhance the mechanical stability of the probe module assembly (10, 100, 200, 60, 300, 50). The shape of the bridge beam 58 may be optimized to mitigate deflection under load. The probe support assembly 50 of the present disclosure may be used to provide precise alignment of probe needles 10 and to minimize mechanical deformation in the probe needles 10 to maintain signal integrity and to provide reliable testing of the DUT to be used.

According to an aspect of the present disclosure, the probe support assembly 50 of the present disclosure comprises at least one piezoelectric device array 40 containing a plurality of piezoelectric unit devices. The at least one piezoelectric device array 40 is disposed between structural components such as the pusher 54, backer 56, and stiffener 52. Each of the piezoelectric unit devices comprises a respective piezoelectric sensor.

In the first exemplary probe module assembly (10, 100, 200, 60, 300, 50) illustrated in FIG. 2A-2D, the at least one piezoelectric device array 40 comprises a proximal piezoelectric device array 40A disposed between the probe card 300 and the pusher 54 and positioned within the opening through the stiffener 52, an intermediate piezoelectric device array 40B disposed between the pusher 54 and the backer 56 and positioned within the opening through the stiffener 52, and distal piezoelectric device array 40C disposed between the backer 56 and the bridge beam 58. The combination of the stiffener 52, the proximal piezoelectric device array 40A, the pusher 54, the intermediate piezoelectric device array 40B, the backer 56, the distal piezoelectric device array 40C, and the bridge beam 58 may be assembled in a manner that minimizes the tilting of the top surface of the bridge beam 58 relative to the bottom surface of the stiffener 52. Thus, the probe support assembly 50 of the present disclosure may be formed by assembling at least the pusher 54, the backer 56, and a plurality of piezoelectric unit devices along a vertical direction.

Generally, the probe support assembly 50 comprises a vertical stack including a pusher 54 and a backer 56, and at least one piezoelectric device array 40 is disposed on the probe card 300. In embodiments in which at least one additional piezoelectric device array 40 is present in the probe support assembly 50, the at least one additional piezoelectric device array 40 may be disposed during formation of the probe support assembly 50 such that a first piezoelectric device array 40 (which may be, for example, the proximal piezoelectric device array 40A or the intermediate piezoelectric device array 40B) is in contact with the pusher 54, and a second piezoelectric device array 40 (which may be, for example, the intermediate piezoelectric device array 40B or the distal piezoelectric device array 40C) is in contact with the backer 56. Each plurality of piezoelectric unit devices within a respective piezoelectric device array 40 may be arranged as a two-dimensional array of piezoelectric sensors during, and after, assembly of the probe support assembly 50.

Generally, each piezoelectric device array 40 may be electrically connected to a respective subset of the signal and power cables 810. The signal and power cables 810 comprise electrically conductive paths between the at least one piezoelectric device array 40 and the piezoelectric sensing circuit 820 within the tester electronics unit 800, and between the at least one piezoelectric device array 40 and the reverse-piezoelectric driver circuit 830 within the tester electronics unit 800. The combination of the contact interface substrate 200, the probe card 300, and the probe support assembly 50 may be attached to a tester head 920.

A plate assembly 100 is provided. The plate assembly 100 may include an upper guide plate 20 which may include an upper array of upper holes 21 therethrough, a lower guide plate 80 may include a lower array of lower holes 81 therethrough, and a dielectric spacer plate 30 located between the upper guide plate 20 and the lower guide plate 80 and comprising a respective opening 31 therethrough. The lower guide plate 80 may be vertically spaced from the upper guide plate 20 by a dielectric spacer plate 30. The upper guide plate 20 includes an upper array of upper holes 21 therethrough, the lower guide plate 80 includes a lower array of lower holes 81 therethrough, and the dielectric spacer plate 30 comprises an opening 31 therethrough.

In one embodiment, the dielectric spacer plate 30 may comprise at least two guide openings 39 therethrough, and at least two fixture elements 92 may vertically extend through the guide opening 39 within the dielectric spacer plate 30. In one embodiment, the upper guide plate 20 comprises at least two threaded openings 29 therethrough, and the lower guide plate 80 comprises at least two lower guide openings 89 therethrough. In one embodiment, each of the at least two fixture elements 92 may vertically extend through a respective one of the lower guide openings 89 and through an opening 39 within the dielectric spacer plate 30, and may engage the thread of a respective one of the threaded openings 29.

An array of probe needles 10 may be inserted into the plate assembly 100. Each of the probe needles 10 may be inserted from the top side of the plate assembly 100 through the array of upper holes 21 in the upper guide plate 20, through the opening 31 in the dielectric spacer plate 30, and through the array of lower holes 81 in the lower guide plate 80. The probe needles 10 may be arranged as a two-dimensional periodic array of probe needles 10. Each of the probe needles may have a wider probe needle tail having a diameter greater than the diameter of the holes in the upper guide plate 20. The probe needles 10 can be inserted from the top side into the plate assembly 100, and the smaller diameter of the holes in the upper guide plate 20 relative to the diameter of the probe needle tails prevent the probe needles 10 from falling through the holes in the upper guide plate 20.

The plate assembly 100 can be attached to the printed circuit board 300 through the jig 60. The fixture elements 62 may be employed to affix the plate assembly 100 to the printed circuit board 300 while a jig 60 is interposed between the plate assembly 100 and the printed circuit board 300. The fixture elements 62 may be adjusted to apply pressure to the array of probe needles 10 such that the array of probe needles 10 pushed against the probe contact pads 220. The plate assembly 100 may be used to align the array of probe needles 10 to the probe contact pads 220, and to attach the array of probe needles 10 to the probe contact pads 220. In one embodiment, the dielectric spacer plate 30 may include an outer periphery and an inner periphery that is laterally surrounded by, and is spaced from, the outer periphery. The dielectric spacer plate 30 laterally surrounds each probe needle 10 within the array of probe needles 10.

The jig 60 may be used to attach the plate assembly 100 to the bottom side of the probe card 300. The jig 60 may laterally surround the contact interface substrate 200. The jig 60 may be provided with mechanical features designed to provide mechanical stability to the plate assembly 100. In a non-limiting illustrative example, the jig 60 may comprise threaded holes configured to mate with fixture elements 62, which may be bolts or screws. Optionally, the bottom surface of the contact interface substrate 200 may be provided with additional mechanical features designed to provide attachment of the plate assembly 100. In a non-limiting illustrative example, the contact interface substrate 200 may comprise additional threaded holes configured to mate with additional fixture elements 92, which may be bolts or screws.

In one embodiment, the contact interface substrate 200 may include at least two mating fixture elements configured to mate with the fixture elements 62. For example, the contact interface substrate 200 may include two or more threaded holes configured to accommodate, and form a stable mechanical support for, a thread of a bolt which may form a respective fixture element 62. In an illustrative example, the at least two fixture elements 62 may include at least two threaded bolts or at least two screws.

Thus, the probe module assembly (10, 100, 200, 60, 300, 50) comprises a probe card assembly (10, 100, 200, 60, 300) and a probe support assembly 50. The probe card assembly (10, 100, 200, 60, 300) includes a probe card 300 with integrated circuits and a probe interface assembly (10, 100, 200, 60).

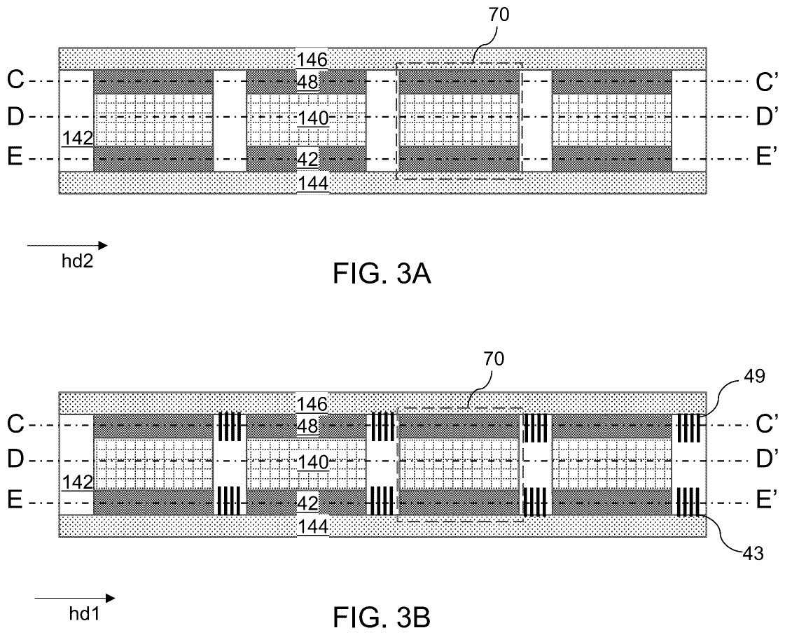

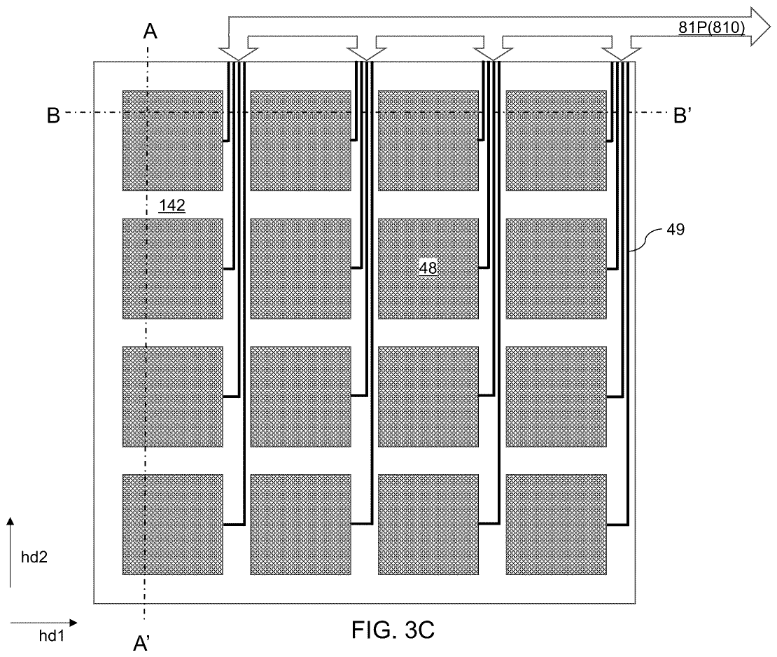

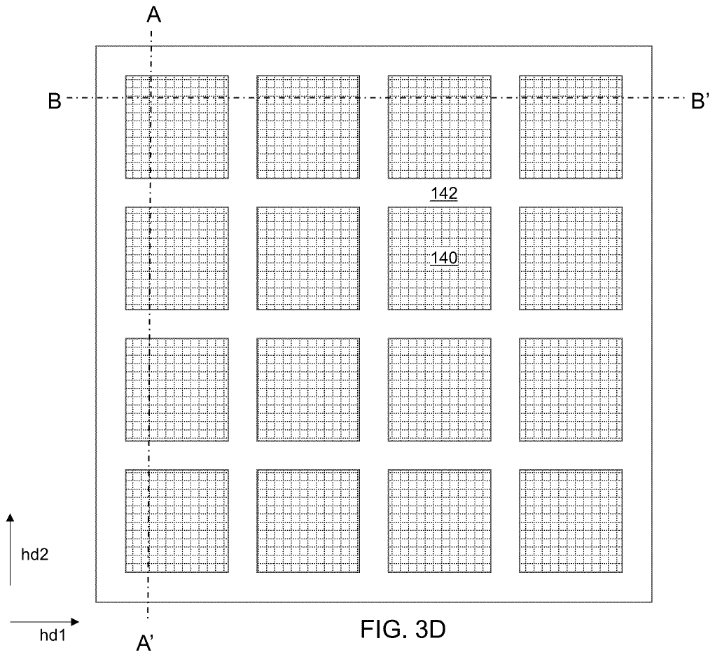

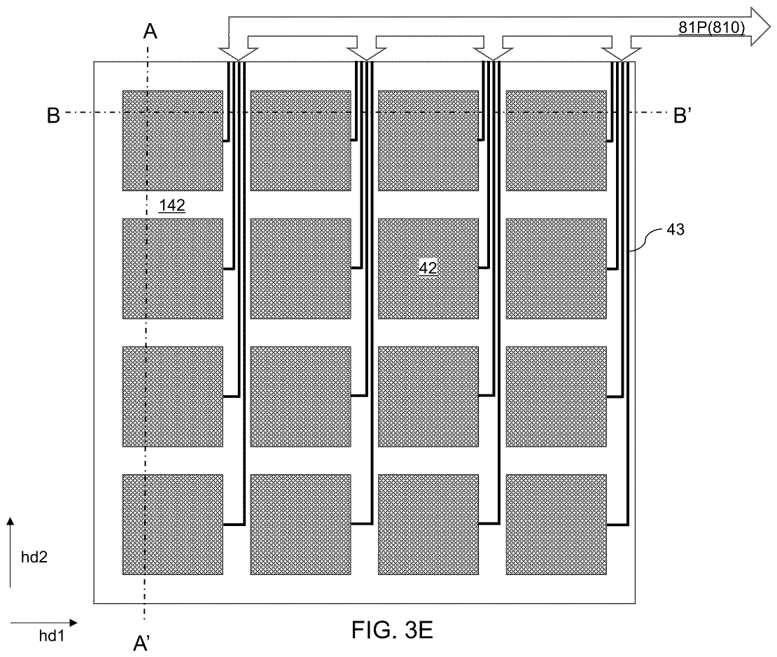

Referring to FIG. 3A-3E, a piezoelectric device array 40 according to an embodiment of the present disclosure is illustrated in various views. FIG. 3A is a first vertical cross-sectional view of the piezoelectric device array 40 according to an embodiment of the present disclosure. FIG. 3B is a second vertical cross-sectional view of the piezoelectric device array 40 according to an embodiment of the present disclosure. FIG. 3C is a horizontal cross-sectional view of the piezoelectric device array 40 along the horizontal plane C-C′ of the piezoelectric device array 40 of FIGS. 3A and 3B. FIG. 3D is a horizontal cross-sectional view of the piezoelectric device array 40 along the horizontal plane D-D′ of the piezoelectric device array 40 of FIGS. 3A and 3B. FIG. 3E is a horizontal cross-sectional view of the piezoelectric device array 40 along the horizontal plane E-E′ of the piezoelectric device array 40 of FIGS. 3A and 3B. The vertical plane A-A′ in FIGS. 3C, 3D, and 3E is the cut plane of the first vertical cross-sectional view of FIG. 3A. The vertical plane B-B′ in FIGS. 3C, 3D, 3E is the cut plane of the second vertical cross-sectional view of FIG. 3B. The piezoelectric device array 40 illustrated in FIG. 3A-3G may be incorporated into the probe module assembly (10, 100, 200, 60, 300, 50) in FIG. 2A-2D as any of the piezoelectric device arrays (40A, 40B, 40C).

The piezoelectric device array 40 illustrated in FIG. 3A-3E comprises an array of piezoelectric unit devices 70. The array of piezoelectric unit devices 70 may comprise a two-dimensional array of piezoelectric unit devices 70. The two-dimensional array of piezoelectric unit devices 70 may comprise an M×N rectangular array of piezoelectric unit devices 70 in which M and N are integers greater than 1, a hexagonal array of piezoelectric unit devices 70, a radial and azimuthal array of piezoelectric unit devices 70 in which piezoelectric unit devices 70 are located at different radial distances from a geometrical center and at different azimuthal angles, or any other type of two-dimensional array. While the present disclosure is described using a configuration in which the piezoelectric unit devices 70 are arranged in a 4×4 rectangular array configuration, alternative configurations for a two-dimensional array of piezoelectric unit devices 70 are expressly contemplated herein.

The piezoelectric device array 40 comprises a two-dimensional array of piezoelectric unit devices 70. In one embodiment, each of the piezoelectric unit devices 70 comprises a vertical stack containing, from bottom to top, a bottom electrode 42, a piezoelectric material portion 140, and a top electrode 48. Each piezoelectric unit device 70 includes a piezoelectric material portion 140 disposed between a bottom electrode 42 and a top electrode 48.

Each piezoelectric unit device 70 is configured to detect deformation via the forward piezoelectric effect, and to generate compensatory forces via the reverse piezoelectric effect. Signals generated from pairs of a bottom electrode 42 and a top electrode 48 in the piezoelectric device array 40 are transmitted via signal and power cables 810 to the piezoelectric sensing circuit 820 (shown in FIG. 1). Compensatory actuation signals are generated by the reverse-piezoelectric driver circuit 830 (shown in FIG. 1), and are applied to pairs of a bottom electrode 42 and a top electrode 48 in the piezoelectric device array 40 to actively compensate for mechanical deformations and restore planarity in the contact interface.

Each piezoelectric material portion 140 comprises a single crystalline piezoelectric material portion. For example, each piezoelectric material portion 140 may consist of a respective single crystalline material portion of a piezoelectric material. Exemplary piezoelectric materials that may be used for the piezoelectric material portion 140 within the piezoelectric unit devices 70 include lithium niobate (LiNbO₃), barium titanate (BaTiO₃), lead zirconate titanate (PZT), zinc oxide (ZnO), and aluminum nitride (AlN). Generally, a piezoelectric material having a piezoelectric coefficient d₃₃>0.01 pm/V is preferred to provide optimized contact interfaces for the purpose of utilizing both forward and reverse piezoelectric effects. The thickness of each piezoelectric material portion 140 may be in a range from 50 nm to 500 nm, although lesser or greater thicknesses may also be used.

The piezoelectric coefficient d₃₃ is defined as the electrical displacement generated in the direction of polarization per unit of applied mechanical stress along the same axis. This coefficient quantifies the material's electrical response to mechanical stress along the direction of polarization. Materials with higher d₃₃ values exhibit more pronounced piezoelectric effects, making them advantageous for applications requiring efficient energy conversion between mechanical and electrical forms. The piezoelectric response of these materials is influenced by their crystallographic orientation. Aligning the crystallographic direction of the piezoelectric material portions 140 along the upward vertical direction or the downward vertical direction is essential to generate reliable piezoelectric effects. This alignment ensures that the applied mechanical stress effectively induces polarization in the desired direction, thereby optimizing the material's piezoelectric response. By selecting appropriate piezoelectric materials with suitable d₃₃ values for the piezoelectric material portion 140, and by aligning the crystallographic direction that generates the maximum piezoelectric effect along the vertical direction, the piezoelectric device array 40 is configured to generate signals based on the forward piezoelectric effect, and to react to control signals that trigger local vertical compression or expansion based on the reverse piezoelectric effect.

Each bottom electrode 42 contacts a bottom surface of a respective piezoelectric material portion 140. Each bottom electrode 42 comprises a metallic material such as Au, Ag, Pt, Al, or Cu. The thickness of each bottom electrode 42 may be in a range from 50 nm to 200 nm, although lesser or greater thicknesses may also be used.

Each top electrode 48 contacts a top surface of a respective piezoelectric material portion 140. Each top electrode 48 comprises a metallic material such as Au, Ag, Pt, Al, or Cu. The thickness of each top electrode 48 may be in a range from 50 nm to 200 nm, although lesser or greater thicknesses may also be used.

The piezoelectric unit devices 70 may be formed by providing a single crystalline piezoelectric material layer having a piezoelectric crystallographic orientation along a thickness direction. As used herein, the piezoelectric crystallographic orientation refers to the orientation of a single crystalline piezoelectric material that provides a maximum piezoelectric voltage per external normal stress. A first conductive layer may be formed on one side of the single crystalline piezoelectric material layer, and a second conductive layer may be formed on another side of the single crystalline piezoelectric material layer.

The layer stack including the first conductive layer, the single crystalline piezoelectric material layer, the second conductive layer be diced to form piezoelectric unit devices 70. Each piezoelectric material portion 140 in a piezoelectric unit device 70 is a diced portion of the single crystalline piezoelectric material layer, each bottom electrode 42 in a piezoelectric unit device 70 is a diced portion of the first conductive layer, and each top electrode 48 in a piezoelectric unit device 70 is a diced portion of the second conductive layer. The lateral dimensions of each piezoelectric unit device 70, such as a length along a first horizontal direction hd1 or a width along a second horizontal direction hd2, may be in a range from 50 microns to 2 mm, although lesser or greater dimensions may also be used.

A bottom dielectric plate 144 comprising a dielectric material may be provided. The bottom dielectric plate 144 comprises a dielectric material such as a polymer material or mylar, and may have a thickness in range from 10 microns to 200 microns, although lesser and greater thicknesses may also be used. A two-dimensional array of piezoelectric unit devices 70 may be disposed on the top surface of the bottom dielectric plate 144. In embodiments in which an M×N rectangular array of piezoelectric unit devices 70 is formed, the piezoelectric unit devices 70 may have first periodicity along the first horizontal direction hd1, and second periodicity along the second horizontal direction hd2.

Bottom signal wires 43 may be formed in the gaps within the array of piezoelectric unit devices 70 such that each of the bottom signal wires 43 has a first end that is electrically connected to a respective bottom electrode 42. A first dielectric gap-fill material portion may be formed to cover the bottom signal wires 43. Top signal wires 49 may be formed in the gaps within the array of piezoelectric unit devices 70 such that each of the top signal wires 49 has a first end that is electrically connected to a respective top electrode 48. A second dielectric gap-fill material portion may be formed to cover the top signal wires 49.

The combination of the first dielectric gap-fill material portion and the second dielectric gap-fill material portion constitutes a dielectric array frame 142. The dielectric array frame comprises a dielectric material such as resin, epoxy, polyimide, or silicone. The top surface of the dielectric array frame 142 may be planarized to a level that is coplanar with the top surfaces of the piezoelectric unit devices 70. A top dielectric plate 146 may be disposed on the top surfaces of the array of piezoelectric unit devices 70 and on the top surface of the dielectric array frame 142.

The bottom signal wires 43 and the top signal wires 49 are connected to piezoelectric sensing cables 81P, which is a subset of the signal and power cables 810. The piezoelectric sensing cables 81P are configured to be connected to the piezoelectric sensing circuit 820 within the tester electronics unit 800 (see FIG. 1) during a piezoelectric sensing operation through a signal switching system. Further, the piezoelectric signal cables 81P are configured to be connected to the reverse-piezoelectric driver circuit 830 in the tester electronics unit 800 during a reverse-piezoelectric actuation operation through the signal switching system.

A pair of a bottom signal wire 43 and a top signal wire 49 on a piezoelectric unit device 70 constitutes a pair of piezoelectric signal wires (43, 49). A pair of piezoelectric signal wires (43, 49) may be connected to the bottom electrode 42 and the top electrode 48 for each of the piezoelectric unit devices. In an illustrative example, a first end of each of the piezoelectric signal wires (43, 49) may be soldered to a respective one of the bottom electrodes 42 and the top electrodes 48.

The pairs of piezoelectric signal wires (43, 49) may be electrically connected to a piezoelectric sensing circuit, i.e., the piezoelectric sensing circuit 820, in the tester electronics unit 800 during the piezoelectric sensing operation through electronic switches in the tested electronics unit 800. According to an aspect of the present disclosure, the piezoelectric sensing circuit 820 is configured to receive and amplify the piezoelectric sensing signals from the piezoelectric signal wires (43, 49). The combination of a bottom electrode 42, a piezoelectric material portion 140, and a top electrode 48 in a piezoelectric unit device 70 constitutes a piezoelectric sensor (42, 140, 48). In one embodiment, the piezoelectric sensors (42, 140, 48) of the piezoelectric device array 40 may be arranged as a two-dimensional spatial array, and may be configured to generate a two-dimensional matrix of piezoelectric output voltages when the sensed piezoelectric voltages are processed in the piezoelectric sensing circuit.

Generally, piezoelectric sensing signals may be generated as electrical output voltages from the piezoelectric sensors (42, 140, 48). In one embodiment, an areal map of magnitudes of the piezoelectric sensing signals may be generated by a mapping program that runs on the tester electronics unit 800. The polarity of each mechanical actuation signal is selected such that the application of a respective mechanical actuation signal reduces, and/or eliminates, pre-existing mechanical deformation of a corresponding piezoelectric material portion 140. An automated program that runs on the tester electronics unit 800 may be used to calculate the magnitudes and the polarity of at least one mechanical actuation signal to be applied to at least one of the piezoelectric sensors (42, 140, 48) in a subsequent reverse-piezoelectric actuation operation.

The at least one mechanical actuation signal induces a volume change in at least one of the piezoelectric material portions 140 of the piezoelectric unit devices 70 in a manner that compensates for an existing piezoelectric deformation in the at least one of the piezoelectric material portions 140. In one embodiment, a plurality of mechanical actuation signals induces volume changes in a plurality of piezoelectric material portions 140 of the piezoelectric unit devices 70 in a manner that compensates for existing piezoelectric deformations in the plurality of the piezoelectric material portions 140.

In one embodiment, at least one mechanical actuation signal may be applied to at least one of the piezoelectric sensors (42, 140, 48) through the piezoelectric signal cables 81P (which include the bottom signal wires 43 and the top signal wires 49 as terminal portions). Each mechanical actuation signal may be applied across a pair of a bottom electrode 42 and a top electrode 48 of a respective one of the piezoelectric unit devices 70. In one embodiment, the reverse-piezoelectric driver circuit 830 may be configured to apply mechanical actuation signals to each of the piezoelectric unit devices 70.

Each mechanical actuation signal induces a volume change in a respective piezoelectric material portion 140 within a respective one of the piezoelectric sensors (42, 140, 48). In one embodiment, each volume change may compensate for an existing piezoelectric deformation in a respective one of the piezoelectric sensors (42, 140, 48), and may reduce the magnitude of a respective piezoelectric sensing signal from a respective one of the piezoelectric sensors (42, 140, 48). In other words, each piezoelectric material portion 140 may deform under a respective mechanical actuation signal, which induces a reverse piezoelectric effect, and the net result of the application of the mechanical actuation signals may be reduction, and/or elimination, of the deformations in the piezoelectric material portions 140.

Referring collectively to FIG. 2A-3E, each piezoelectric device array 40 may be operated independently to achieve planar alignment relative to its vertically neighboring structural elements, which may include the probe card 300, the pusher 54, the backer 56, and the bridge beam 58. The alignment process may be performed sequentially among the proximal piezoelectric device array 40A, the intermediate piezoelectric device array 40B, and the distal piezoelectric device array 40C. The order of alignment may be chosen freely provided that each piezoelectric device array 40 is aligned in a manner that provides the uniform distribution of vertical pressure across the entire area of the piezoelectric device array 40.

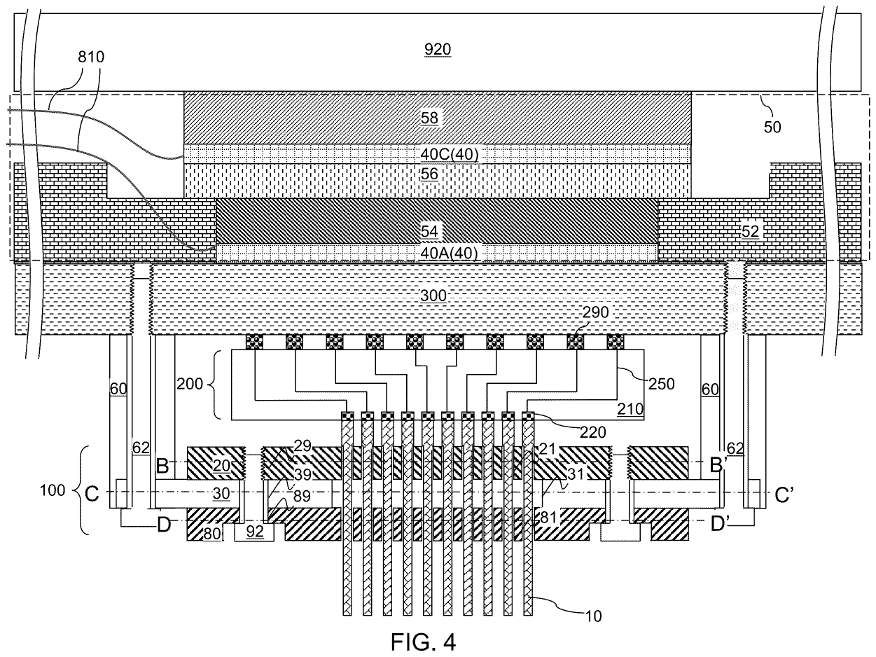

Referring to FIG. 4, a second exemplary probe module assembly (10, 100, 200, 60, 300, 50) according to an embodiment of the present disclosure is illustrated. The second exemplary probe module assembly (10, 100, 200, 60, 300, 50) may be derived from the first exemplary probe module assembly (10, 100, 200, 60, 300, 50) by removing the intermediate piezoelectric device array 40B.

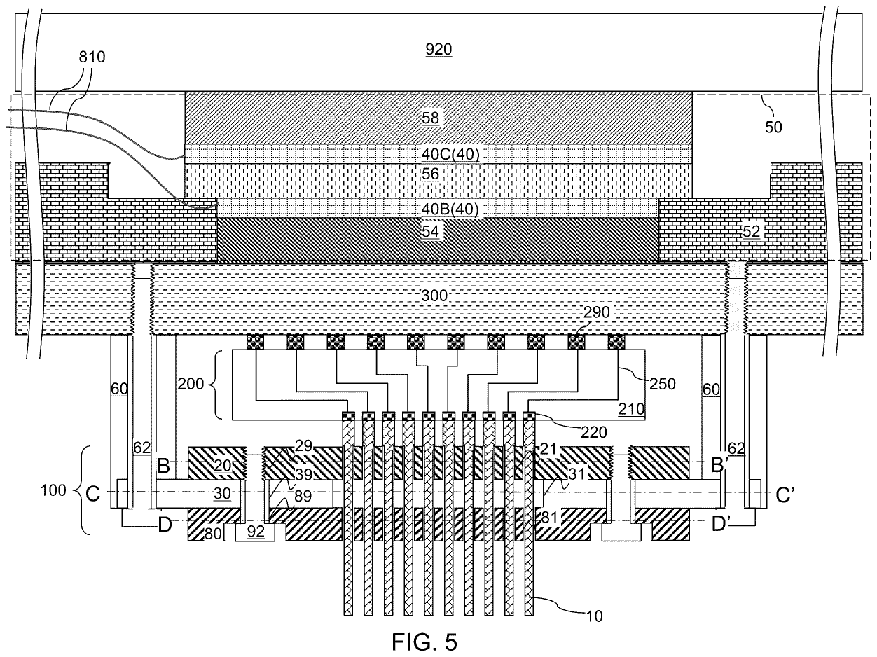

Referring to FIG. 5, a third exemplary probe module assembly (10, 100, 200, 60, 300, 50) according to an embodiment of the present disclosure is illustrated. The third exemplary probe module assembly (10, 100, 200, 60, 300, 50) may be derived from the first exemplary probe module assembly (10, 100, 200, 60, 300, 50) by removing the proximal piezoelectric device array 40A.

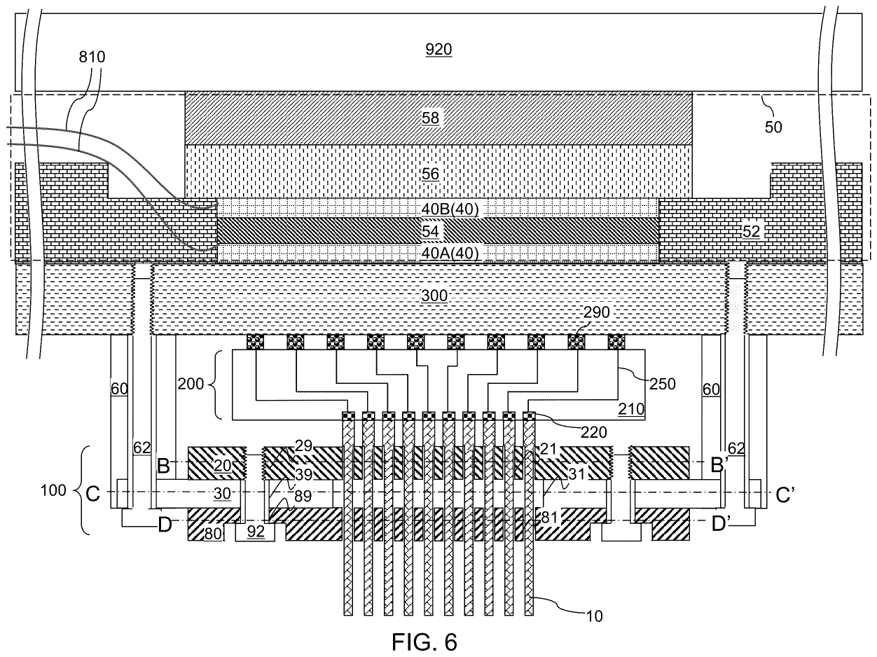

Referring to FIG. 6, a fourth exemplary probe module assembly (10, 100, 200, 60, 300, 50) according to an embodiment of the present disclosure is illustrated. The fourth exemplary probe module assembly (10, 100, 200, 60, 300, 50) may be derived from the first exemplary probe module assembly (10, 100, 200, 60, 300, 50) by removing the distal piezoelectric device array 40C.

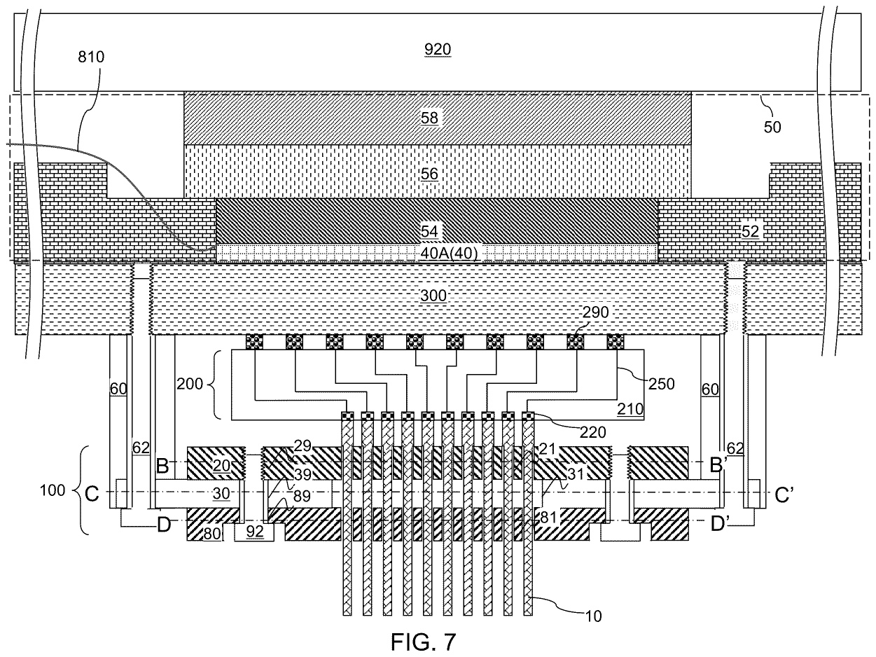

Referring to FIG. 7, a fifth exemplary probe module assembly (10, 100, 200, 60, 300, 50) according to an embodiment of the present disclosure is illustrated. The fifth exemplary probe module assembly (10, 100, 200, 60, 300, 50) may be derived from the first exemplary probe module assembly (10, 100, 200, 60, 300, 50) by removing the intermediate piezoelectric device array 40B and the distal piezoelectric device array 40C.

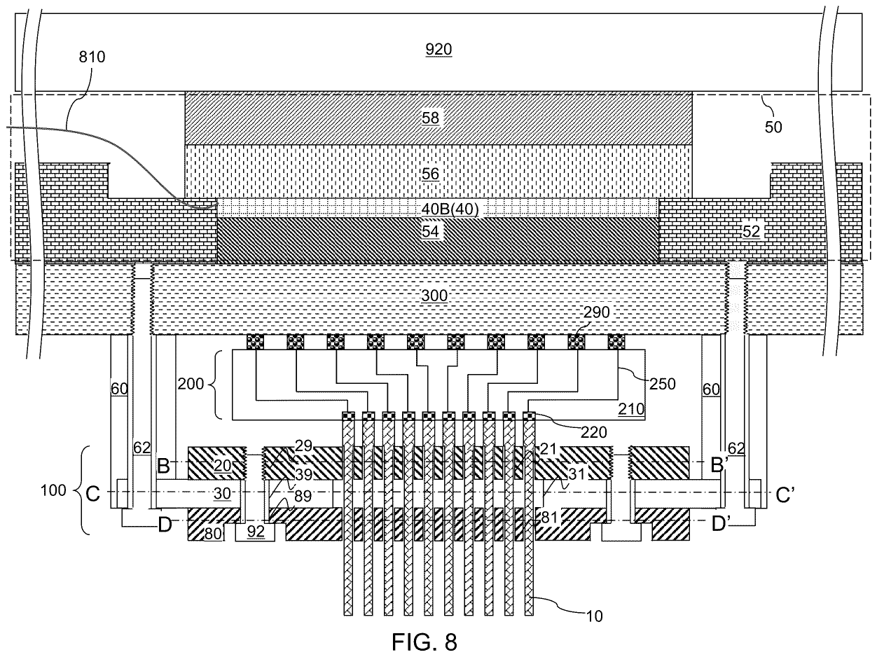

Referring to FIG. 8, a sixth exemplary probe module assembly (10, 100, 200, 60, 300, 50) according to an embodiment of the present disclosure is illustrated. The sixth exemplary probe module assembly (10, 100, 200, 60, 300, 50) may be derived from the first exemplary probe module assembly (10, 100, 200, 60, 300, 50) by removing the proximal piezoelectric device array 40A and the distal piezoelectric device array 40C.

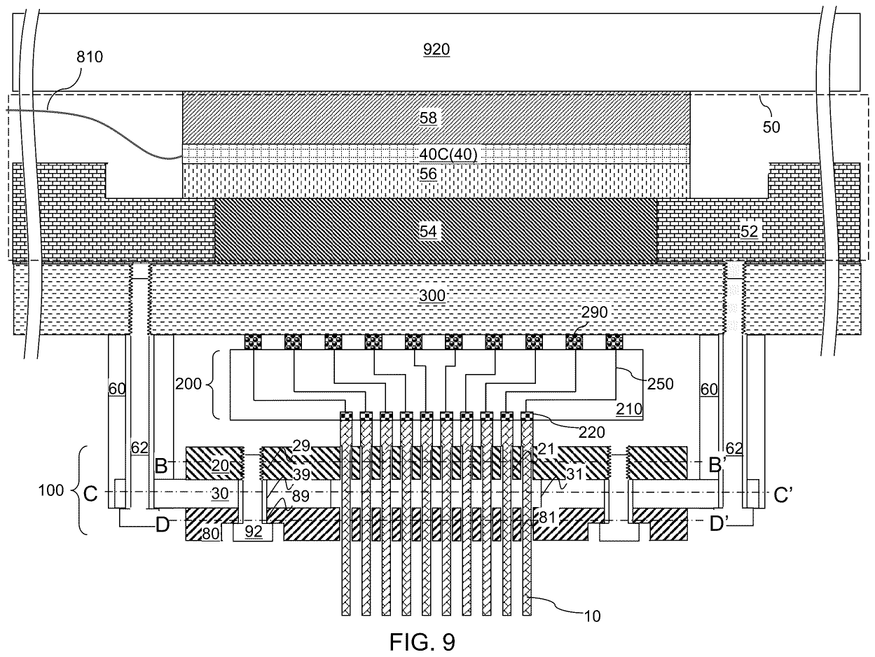

Referring to FIG. 9, a seventh exemplary probe module assembly (10, 100, 200, 60, 300, 50) according to an embodiment of the present disclosure is illustrated. The seventh exemplary probe module assembly (10, 100, 200, 60, 300, 50) may be derived from the first exemplary probe module assembly (10, 100, 200, 60, 300, 50) by removing the proximal piezoelectric device array 40A and the intermediate piezoelectric device array 40B.

Referring collectively to FIGS. 1-9 , the probe module assembly (10, 100, 200, 60, 300, 50) of the present disclosure is configured to provide in-situ planarity compensation during testing. The probe module assembly (10, 100, 200, 60, 300, 50) of the present disclosure eliminates reliance on consumable materials for adjustment and alignment of the probe needles 10 relative to the probe contact pads 220, and allows for immediate electronic correction of alignment and planarity correction without manual intervention. The probe support assembly 50 within the probe module assembly (10, 100, 200, 60, 300, 50) may be provided in various configurations as described above. In some embodiments, the piezoelectric device array 40 may be disposed between the backer 56 and the bridge beam 58. Additionally or alternatively, a piezoelectric device array 40 may be disposed between the probe card 300 and pusher 54. Generally, at least one piezoelectric device array 40 may be disposed between one or more vertically neighboring pairs of structural elements selected from the pusher 54, the backer 56, the bridge beam 58, and the probe card 300.

According to an embodiment of the present disclosure, a test apparatus comprising a probe module assembly (10, 100, 200, 60, 300, 50) is provided. The probe module assembly (10, 100, 200, 60, 300, 50) comprises: a probe card 300; a contact interface substrate 200 comprising probe contact pads 220 and attached to a bottom of the probe card 300; an array of probe needles 10 attached to the probe contact pads 220 and vertically extending downward from the probe contact pads 220; a probe support assembly 50 overlying the probe card 300; and a tester head 920 to which the probe support assembly 50 is attached. The probe support assembly 50 comprises a piezoelectric device array 40 containing a plurality of piezoelectric unit devices 70; and each of the piezoelectric unit devices 70 comprises a respective piezoelectric sensor (42, 140, 48).

In one embodiment, the plurality of piezoelectric unit devices 70 is arranged as a two-dimensional array of piezoelectric sensors (42, 140, 48); and the piezoelectric sensors (42, 140, 48) of the piezoelectric device array 40 are configured to generate a two-dimensional matrix of piezoelectric output voltages. In one embodiment, each of the piezoelectric unit devices 70 comprises a vertical stack containing, from bottom to top, a bottom electrode 42, a bottom electrode 42, a piezoelectric material portion 140, a top electrode 48, and a top electrode 48.

In one embodiment, the test apparatus comprises: pairs of piezoelectric sense signal wires (45, 47) connected to the bottom electrode 42 and the top electrode 48 of a respective one of the piezoelectric unit devices 70; and a piezoelectric sensing circuit 820 configured to receive piezoelectric sensing signals transmitted through the pairs of piezoelectric sense signal wires (45, 47).

In one embodiment, the test apparatus comprises a tester electronics unit 800. The tester electronics unit 800 comprises a reverse-piezoelectric driver circuit 830 configured to generate at least one mechanical actuation signal that induces a volume change in at least one of the piezoelectric material portions 140 of the piezoelectric unit devices 70 in a manner that compensates for an existing piezoelectric deformation in said at least one of the piezoelectric material portions 140 based on an areal map of the magnitudes of the piezoelectric sensing signals. The areal map of magnitudes of the piezoelectric sensing signals may be generated by a two-dimensional data mapping program that runs on the tester electronics unit 800.

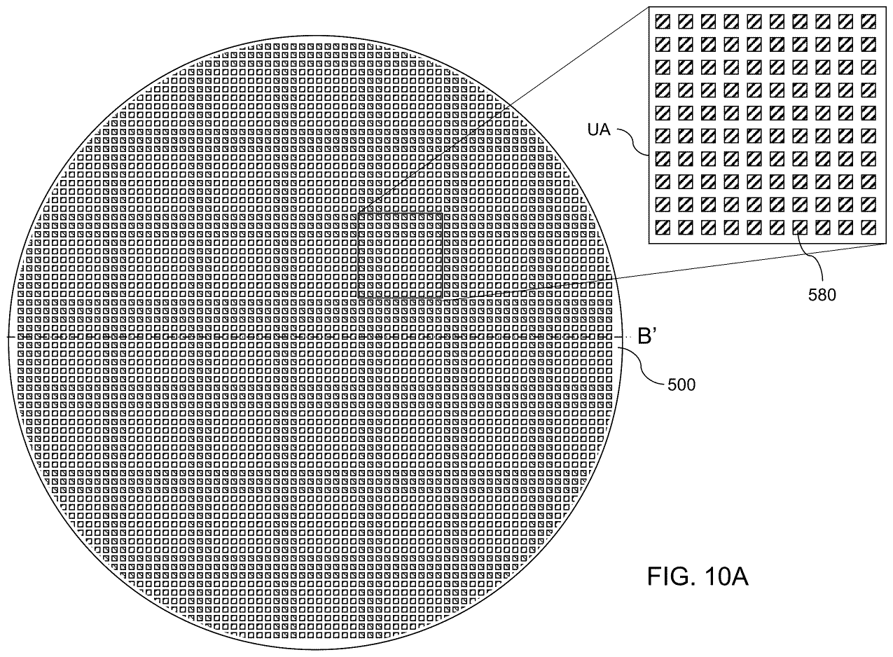

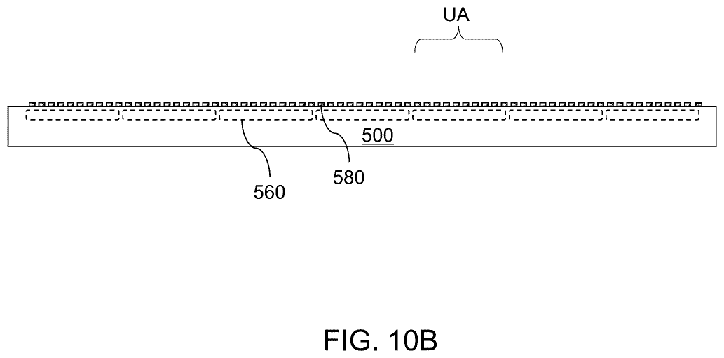

Referring to FIGS. 10A and 10B, a semiconductor wafer 500 including a two-dimensional array of semiconductor dies 560 is illustrated. Each semiconductor die 560 may comprise a respective array of test pads 580. The pattern of a single semiconductor die 560 may be a unit pattern UA, which is repeated within the area of the semiconductor wafer 500 with a two-dimensional periodicity.

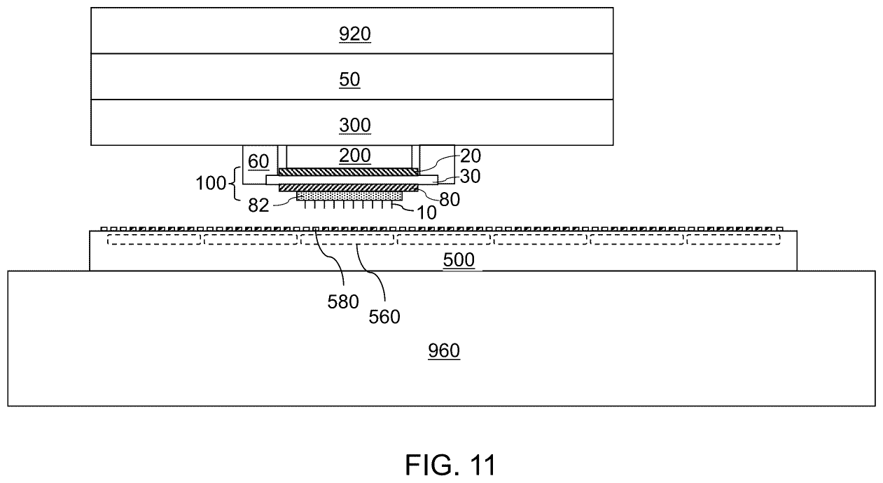

FIG. 11 is a vertical cross-sectional view of a portion of the test apparatus of FIG. 1 during testing of a semiconductor die 560 in the semiconductor wafer 500. Generally, a semiconductor wafer 500 including semiconductor devices may be positioned under the array of probe needles 10. The array of probe needles 10 may be aligned to, and may be disposed on, test pads 580 on the semiconductor wafer 500. Data representing electrical characteristics of the semiconductor devices may be generated by running a test program. In this embodiment, the semiconductor dies 560 may be the device under test 980 illustrated in FIG. 1

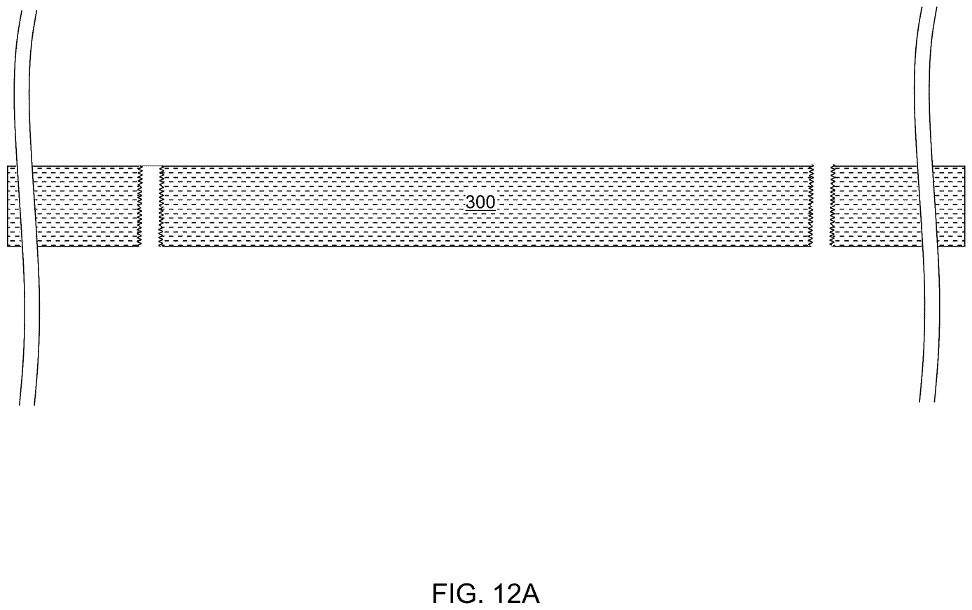

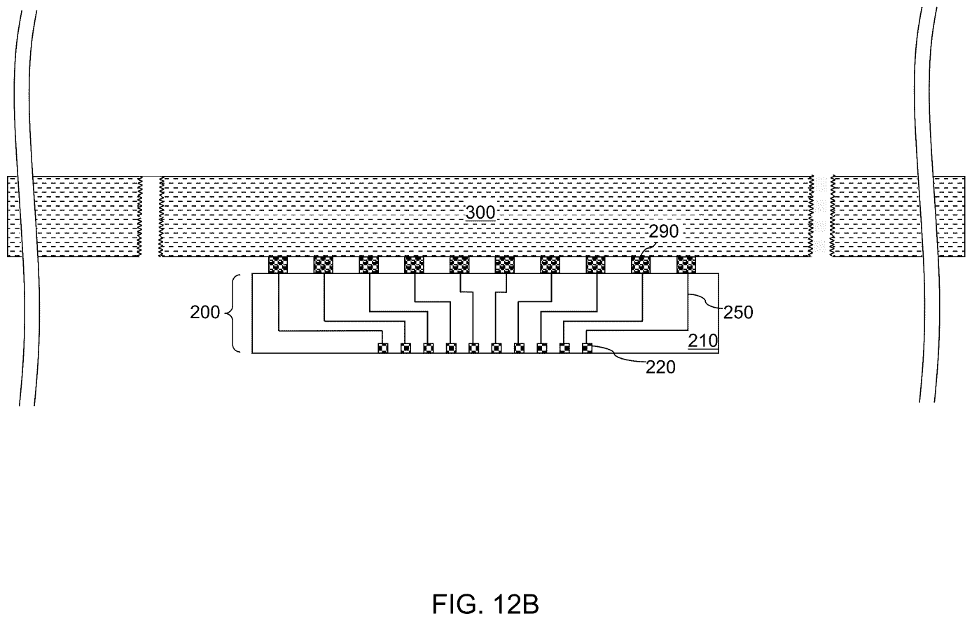

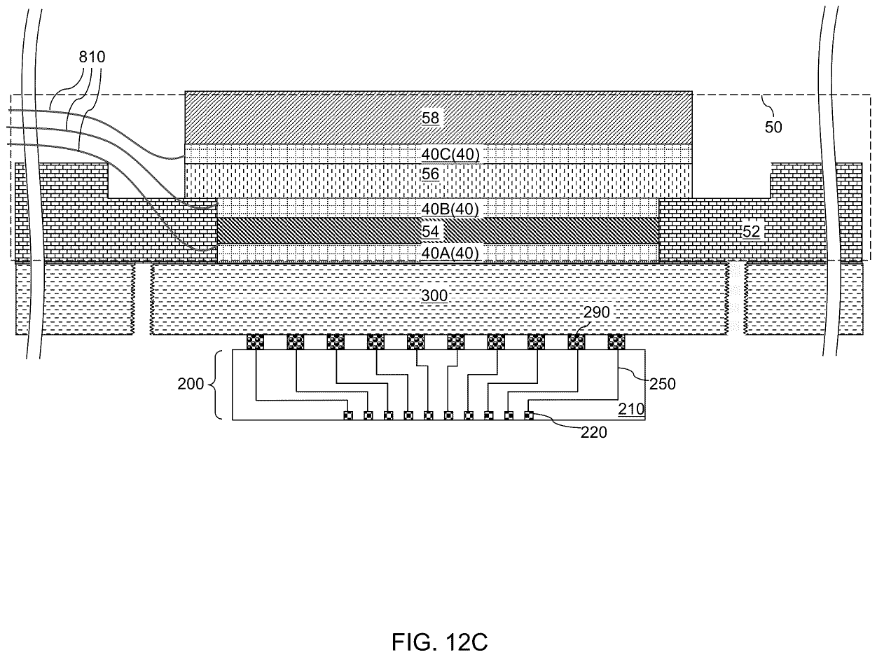

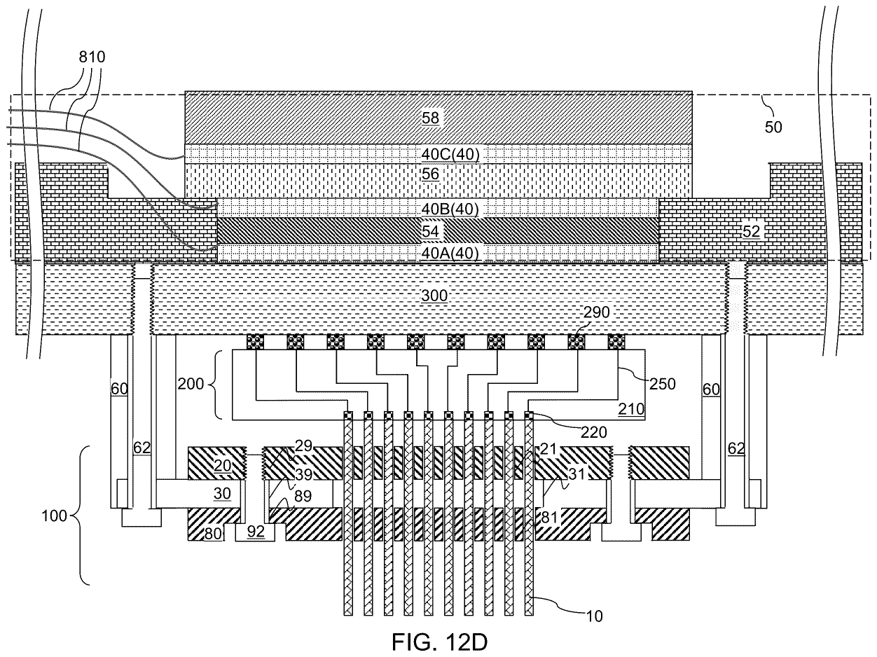

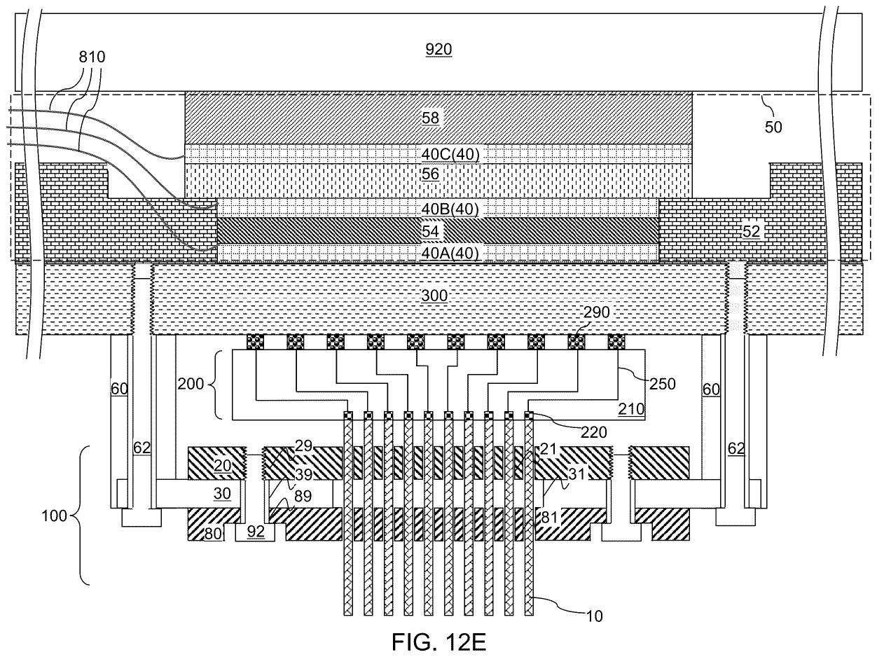

FIG. 12A-12E illustrate a sequence of processing steps that may be used to form a probe module assembly of the present disclosure.

Referring to FIG. 12A, a probe card 300 of the present disclosure may be provided.

Referring to FIG. 12B, a contact interface substrate 200 comprising probe contact pads 220 may be attached to a bottom side of the probe card 300.

Referring to FIG. 12C, a probe support assembly 50 of any configuration of the present disclosure may be formed on the top side of the probe card 300.

Referring to FIG. 12D, a plate assembly 100 and an array of probe needles 10 may be attached to the contact interface substrate 200 employing a jig 60. The plate assembly 100 may include an upper guide plate 20, a lower guide plate 80, and a dielectric spacer plate 30. The plate assembly 100 may include an upper guide plate 20, a lower guide plate 80, and a dielectric spacer plate 30.

Referring to FIG. 12E, an assembly of the probe support assembly 50, the probe card 300, the jig 60, the plate assembly 100, and the array of probe needles 10 may be attached to a tester head 920.

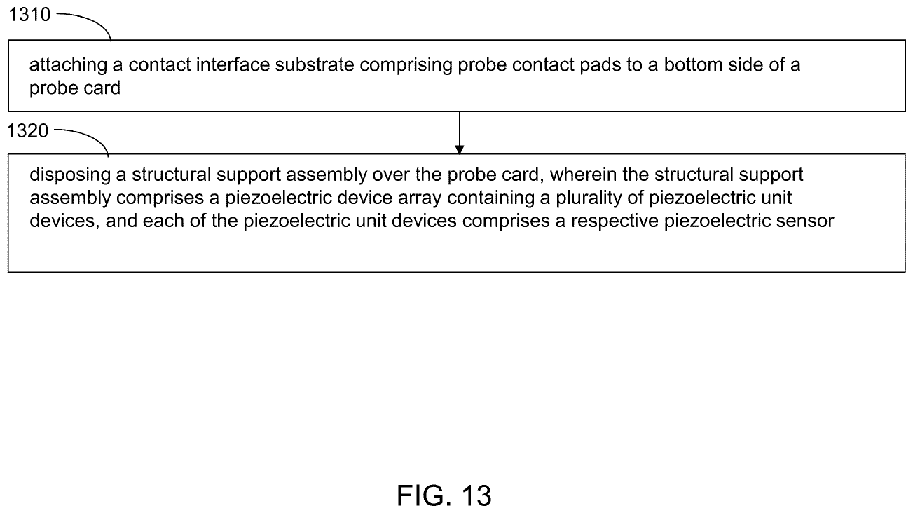

Referring to FIG. 13, a first flowchart illustrates the general processing steps for operating a test apparatus according to an aspect of the present disclosure.

Referring to step 1310 and FIG. 1-9, 12A, and 12B, a contact interface substrate 200 comprising probe contact pads 220 may be attached to a bottom side of a probe card 300.

Referring to step 1320 and FIG. 1-9, and 12C-12E, a probe support assembly 50 may be disposed over a probe card 300. The probe support assembly 50 comprises a piezoelectric device array 40 containing a plurality of piezoelectric unit devices 70. Each of the piezoelectric unit devices 70 comprises a respective piezoelectric sensor (42, 44, 140, 46, 48).

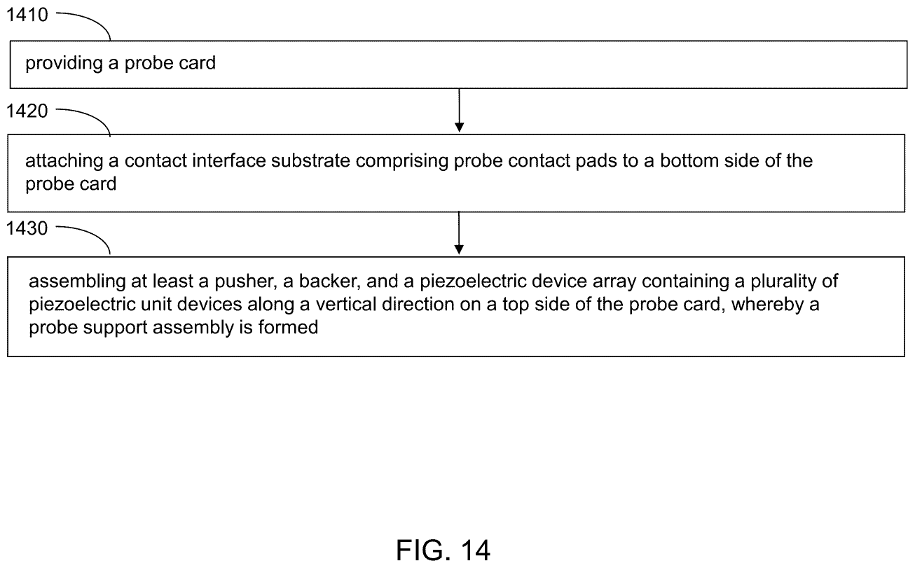

Referring to FIG. 14, a second flowchart illustrates the general processing steps for manufacturing a test apparatus according to an aspect of the present disclosure.

Referring to step 1410 and FIG. 1-9 and 12A, a probe card 300 may be provided.

Referring to step 1420 and FIG. 1-9, 12A, and 12B, a contact interface substrate 200 comprising probe contact pads 220 may be attached to a bottom side of the probe card 300.

Referring to step 1430 and FIG. 1-9 and 12C-12E, at least a pusher 54, a backer 56, and a piezoelectric device array 40 containing a plurality of piezoelectric unit devices 70 is assembled along a vertical direction on a top side of the probe card 300. A probe support assembly 50 is formed.

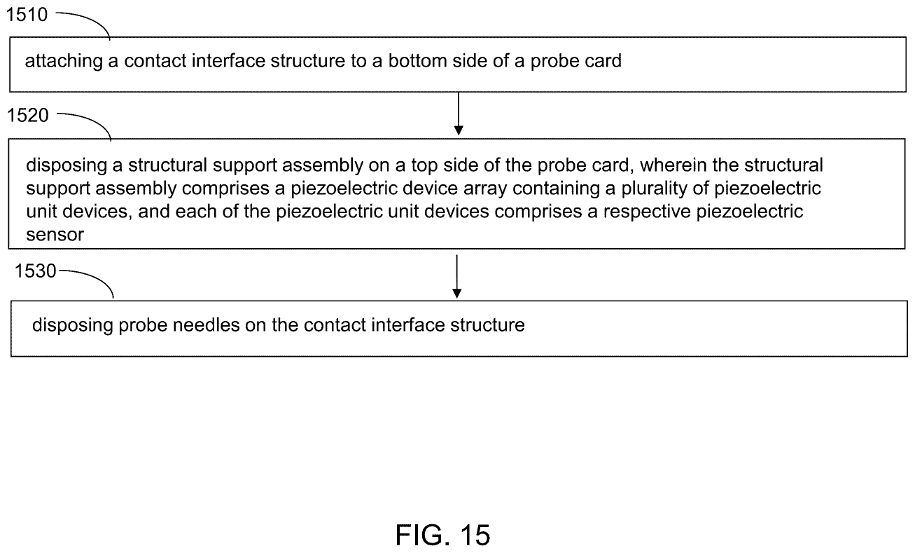

Referring to FIG. 15, a third flowchart illustrates the general processing steps for manufacturing a test apparatus according to an aspect of the present disclosure.

Referring to step 1510 and FIG. 1-9, 12A, and 12B, a contact interface substrate 200 may be attached to a bottom side of a probe card 300.

Referring to step 1520 and FIG. 1-9 and 12C, a probe support assembly 50 may be disposed over a probe card 300. The probe support assembly 50 comprises a piezoelectric device array 40 containing a plurality of piezoelectric unit devices 70. Each of the piezoelectric unit devices 70 comprises a respective piezoelectric sensor (42, 44, 140, 46, 48).

Referring to step 1530 and FIG. 1-9, 12D, and 12E, probe needles 10 can be disposed on the contact interface structure 200.

The planarity compensation mechanism of the present disclosure uses at least one piezoelectric device array 40, and operates by detecting deformation of the piezoelectric material portions 140. The deformation of the piezoelectric material portions 140 generates electrical signals transmitted through the proximal electrodes (44, 46). The piezoelectric sensing circuit 820 within the tester electronics unit 800 amplifies and processes the sensed piezoelectric signals to determine the warpage profile of each piezoelectric device array 40. The reverse-piezoelectric driver circuit 830 within the tester electronics unit 800 transmits actuation signals to the distal electrodes (42, 48) to reduce, or eliminate, the original deformation of the piezoelectric material portions 140, and to counteract the detected warpage. This process may continuously monitor and adjust the planarity of the probe card 300 during testing.

Embodiments of the present disclosure provides real-time compensation for mechanical warpage of the probe card 300 through the integration of piezoelectric sensing and reverse-piezoelectric actuation in at least one integrated structure comprise a respective piezoelectric device array 40, thereby reducing the need for external adjustments. By eliminating consumable materials and associated manual interventions, the probe support assembly 50 of the present disclosure ensures consistent electrical contact during testing. Embodiments of the present disclosure enhance testing stability by addressing probe card warpage and uneven contact surfaces in situ, i.e., during testing, thereby improving the reliability of electrical connections. The modular design of the probe module assembly (10, 100, 200, 60, 300, 50) allows compatibility with various semiconductor testing configurations and across multiple technology generations.

The foregoing outlines features of several embodiments so that those skilled in the art may better understand the aspects of the present disclosure. Each embodiment described using the term “comprises” also inherently discloses that the term “comprises” may be replaced with “consists essentially of” or with the term “consists of” in some embodiments, unless expressly disclosed otherwise herein. Whenever two or more elements are listed as alternatives in a same paragraph or in different paragraphs, a Markush group including a listing of the two or more elements may also be impliedly disclosed. Whenever the auxiliary verb “can” is used in this disclosure to describe formation of an element or performance of a processing step, an embodiment in which such an element or such a processing step is not performed is also expressly contemplated, provided that the resulting apparatus or device may provide an equivalent result. As such, the auxiliary verb “can” as applied to formation of an element or performance of a processing step should also be interpreted as “may” or as “may, or may not” whenever omission of formation of such an element or such a processing step is capable of providing the same result or equivalent results, the equivalent results including somewhat superior results and somewhat inferior results. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method of operating a test apparatus, the method comprising:
attaching a contact interface substrate comprising probe contact pads to a bottom side of a probe card; and disposing a probe support assembly over the probe card, wherein the probe support assembly comprises a piezoelectric device array containing a plurality of piezoelectric unit devices, and each of the piezoelectric unit devices comprises a respective piezoelectric sensor.

2. The method of claim 1, further comprising:
disposing an array of probe needles on the probe contact pads; and
attaching a combination of the probe card, the contact interface substrate, the array of probe needles, and the probe support assembly to a tester head.

3. The method of claim 2, further comprising:
positioning a semiconductor wafer including semiconductor devices under the array of probe needles;
disposing the array of probe needles on test pads on the semiconductor wafer; and
generating data representing electrical characteristics of the semiconductor devices.

4. The method of claim 1, wherein the probe support assembly is formed by assembling at least a pusher, a backer, and the plurality of piezoelectric unit devices along a vertical direction.

5. The method of claim 4, wherein the plurality of piezoelectric unit devices is arranged as a two-dimensional array of piezoelectric sensors during, and after, assembly of the probe support assembly.

6. The method of claim 5, wherein the piezoelectric sensors of the piezoelectric device array are configured to generate a two-dimensional matrix of piezoelectric output voltages.

7. The method of claim 1, wherein each of the piezoelectric unit devices comprises a vertical stack containing, from bottom to top, a bottom electrode, a piezoelectric material portion, and a top electrode.

8. The method of claim 1, further comprising generating an areal map of magnitudes of piezoelectric sensing signals that are generated as electrical output voltages from the piezoelectric sensors.

9. The method of claim 8, further comprising applying at least one mechanical actuation signal to at least one of the piezoelectric sensors, wherein the at least one mechanical actuation signal induces a volume change in each piezoelectric material portion within said at least one of the piezoelectric sensors.

10. The method of claim 1, wherein said volume change compensates for an existing piezoelectric deformation in said at least one of the piezoelectric sensors and reduces a magnitude of a respective piezoelectric sensing signal from said at least one of the piezoelectric sensors.

11. A test apparatus comprising a probe module assembly, the probe module assembly comprising:
a probe card;
a contact interface substrate comprising probe contact pads and attached to a bottom of the probe card;
an array of probe needles attached to the probe contact pads and vertically extending downward from the probe contact pads;
a probe support assembly overlying the probe card; and
a tester head to which the probe support assembly is attached, wherein:
the probe support assembly comprises a piezoelectric device array containing a plurality of piezoelectric unit devices; and
each of the piezoelectric unit devices comprises a respective piezoelectric sensor.

12. The test apparatus of claim 11, wherein:
the plurality of piezoelectric unit devices is arranged as a two-dimensional array of piezoelectric sensors; and
the piezoelectric sensors of the piezoelectric device array are configured to generate a two-dimensional matrix of piezoelectric output voltages.

13. The test apparatus of claim 11, wherein each of the piezoelectric unit devices comprises a vertical stack containing, from bottom to top, a bottom electrode, a piezoelectric material portion, and a top electrode.

14. The test apparatus of claim 13, further comprising pairs of piezoelectric signal wires connected to the bottom electrode and the top electrode of a respective one of the piezoelectric unit devices.

15. The test apparatus of claim 14, further comprising a tester electronics unit, wherein the tester electronics unit comprises a reverse-piezoelectric driver circuit configured to generate at least one mechanical actuation signal that induces a volume change in at least one of the piezoelectric material portions of the piezoelectric unit devices in a manner that compensates for an existing piezoelectric deformation in said at least one of the piezoelectric material portions based on an areal map of the magnitudes of the piezoelectric sensing signals.

16. A method forming a test apparatus, comprising:
providing a probe card;
attaching a contact interface substrate comprising probe contact pads to a bottom side of the probe card; and
assembling at least a pusher, a backer, and a piezoelectric device array containing a plurality of piezoelectric unit devices along a vertical direction on a top side of the probe card, whereby a probe support assembly is formed.

17. The method of claim 16, further comprising;
attaching an array of probe needles to the probe contact pads; and
attaching the probe support assembly to a tester head.

18. The method of claim 16, wherein the piezoelectric device array is disposed on the probe card, the pusher, or the backer.

19. The method of claim 18, further comprising disposing an additional piezoelectric device array in the probe support assembly during formation of the probe support assembly such that said piezoelectric device array is in contact with the pusher, and said additional piezoelectric device array is in contact with the backer.

20. The method of claim 16, wherein:
each of the piezoelectric unit devices comprises a vertical stack containing, from bottom to top, a bottom electrode, a piezoelectric material portion, and a top electrode;
the method comprises connecting a pair of piezoelectric signal wires to the bottom electrode and the top electrode for each of the piezoelectric unit devices;
the method comprises electrically connecting the pairs of piezoelectric signal wires to a piezoelectric sensing circuit in a tester electronics unit which is configured to generate piezoelectric sensing signals; and
the method comprises generating at least one mechanical actuation signal using a reverse-piezoelectric driver circuit in the tester electronic unit, wherein the at least one mechanical actuation signal induces a volume change in at least one of the piezoelectric material portions of the piezoelectric unit devices in a manner that compensates for an existing piezoelectric deformation in said at least one of the piezoelectric material portions.
